(19) United States
(12) Patent Application Publication
(10) Pub. No.: US 2025/0248070 A1
(43) Pub. Date: Jul. 31, 2025

(54) SEMICONDUCTOR DEVICE AND MANUFACTURING METHOD THEREOF

(71) Applicant: Fujian Jinhua Integrated Circuit Co., Ltd., Quanzhou City (CN)

(72) Inventors: Xiaoqin Xiao, Quanzhou City (CN); Chia-Wei Wu, Quanzhou City (CN)

(73) Assignee: Fujian Jinhua Integrated Circuit Co., Ltd., Quanzhou City (CN)

(21) Appl. No.: 18/595,332

(22) Filed: Mar. 4, 2024

(30) Foreign Application Priority Data
Jan. 30, 2024 (CN) 202410129260.2

(51) Int. Cl. H01L 29/49; H01L 21/3115; H01L 29/66; H01L 29/786

(52) U.S. Cl. CPC H10D 30/6739; H01L 21/31155; H10D 30/031; H10D 30/6728

(57) ABSTRACT

A semiconductor device and a manufacturing method thereof are in the present invention. The semiconductor device includes a substrate, a source structure, a semiconductor structure, a gate structure, a barrier pattern. The source structure is disposed on the substrate, the semiconductor structure is disposed above the source structure in a vertical direction, and the gate structure is disposed above the source structure and surrounds the semiconductor structure in a horizontal direction. The barrier pattern is disposed between the gate structure and the semiconductor structure in the horizontal direction. The gate structure surrounds the barrier pattern in the horizontal direction, and the barrier pattern surrounds the semiconductor structure in the horizontal direction. Accordingly, the operation performance of the semiconductor device may be improved.

### BACKGROUND OF THE INVENTION

### 1. Field of the Invention

The present invention relates to a semiconductor device and a manufacturing method thereof, and more particularly, to a semiconductor device including a barrier pattern and a manufacturing method thereof.

### 2. Description of the Prior Art

The development of semiconductor integrated circuit technology progresses continuously and circuit designs in products of the new generation become smaller and more complicated than those of the former generation. The amount and the density of the functional devices in each chip region are increased constantly according to the requirements of innovated products, and the size of each device has to become smaller accordingly. The conventional planar metal-oxide-semiconductor (MOS) transistor has difficulty when scaling down in the development of the semiconductor device. Therefore, the stereoscopic transistor technology or the non-planar transistor technology that allows smaller size and higher performance is developed to replace the planar MOS transistor for reducing the dimension of the transistor unit and/or improving the operation performance of the transistor unit.

### SUMMARY OF THE INVENTION

A semiconductor device and a manufacturing method thereof are provided in the present invention. A barrier pattern is disposed between a gate structure and a semiconductor structure for improving operation performance of the semiconductor device.

According to an embodiment of the present invention, a semiconductor device is provided. The semiconductor device includes a substrate, a source structure, a semiconductor structure, a gate structure, and a barrier pattern. The source structure is disposed on the substrate, the semiconductor structure is disposed above the source structure in a vertical direction, and the gate structure is disposed above the source structure and surrounds the semiconductor structure in a horizontal direction. The barrier pattern is disposed between the gate structure and the semiconductor structure in the horizontal direction. The gate structure surrounds the barrier pattern in the horizontal direction, and the barrier pattern surrounds the semiconductor structure in the horizontal direction.

According to an embodiment of the present invention, a manufacturing method of a semiconductor device is provided. The manufacturing method includes the following steps. A substrate is provided, and a source structure is formed above the substrate. A gate structure is formed above the source structure in a vertical direction. A barrier pattern is formed above the source structure, and the gate structure surrounds the barrier pattern in a horizontal direction. A semiconductor structure is formed above the source structure, and the gate structure surrounds the semiconductor structure in the horizontal direction. The barrier pattern surrounds the semiconductor structure in the horizontal direction, and the barrier pattern is located between the gate structure and the semiconductor structure in the horizontal direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a cross-sectional schematic drawing illustrating a semiconductor device according to a first embodiment of the present invention.

FIGS. 2-10 are schematic drawings illustrating a manufacturing method of a semiconductor device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, and FIG. 10 is a schematic drawing in a step subsequent to FIG. 9.

FIG. 11 is a schematic drawing illustrating a manufacturing method of a semiconductor device according to another embodiment of the present invention.

FIG. 12 is a cross-sectional schematic drawing illustrating a semiconductor device according to a second embodiment of the present invention.

FIGS. 13-16 are schematic drawings illustrating a manufacturing method of a semiconductor device according to an embodiment of the present invention, wherein FIG. 14 is a schematic drawing in a step subsequent to FIG. 13, FIG. 15 is a schematic drawing in a step subsequent to FIG. 14, and FIG. 16 is a schematic drawing in a step subsequent to FIG. 15.

FIG. 17 is a schematic drawing illustrating a manufacturing method of a semiconductor device according to another embodiment of the present invention.

FIG. 18 is a cross-sectional schematic drawing illustrating a semiconductor device according to a third embodiment of the present invention.

FIG. 19 is a top view schematic drawing illustrating a portion of a semiconductor device according to an embodiment of the present invention.

### DETAILED DESCRIPTION

To provide a better understanding of the presented invention, preferred embodiments will be described in detail. The preferred embodiments of the present invention are illustrated in the accompanying drawings with numbered elements. In addition, the technical features in different embodiments described in the following may be replaced, recombined, or mixed with one another to constitute another embodiment without departing from the spirit of the present invention.

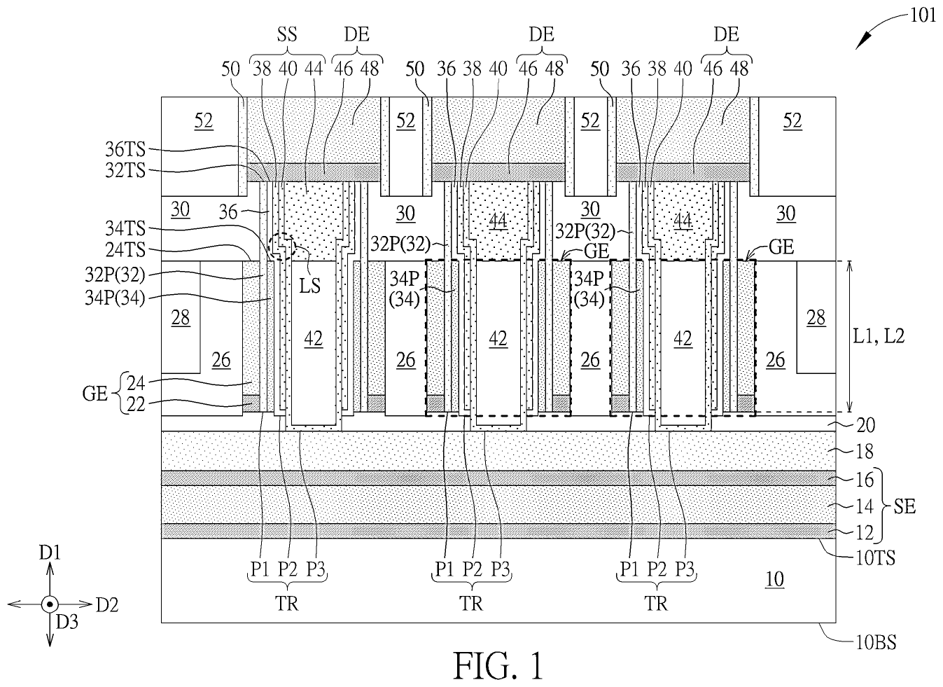

Please refer to FIG. 1. FIG. 1 is a cross-sectional schematic drawing illustrating a semiconductor device 101 according to a first embodiment of the present invention. As shown in FIG. 1, the semiconductor device 101 includes a substrate 10, a source structure SE, a semiconductor structure SS, a gate structure GE, and a barrier pattern 34P. The source structure SE is disposed on the substrate 10, the semiconductor structure SS is disposed above the source structure SE in a vertical direction D1, and the gate structure GE is disposed above the source structure SE and surrounds the semiconductor structure SS in a horizontal direction. It is worth noting that the horizontal direction described in the present invention may include a horizontal direction D2, a horizontal direction D3, and/or other horizontal directions orthogonal to the vertical direction D1. The barrier pattern 34P is disposed between the gate structure GE and the semiconductor structure SS in the horizontal direction. The gate structure GE surrounds the barrier pattern 34P in the horizontal direction, and the barrier pattern 34P surrounds the semiconductor structure SS in the horizontal direction. The barrier pattern 34P disposed between the gate structure GE and the semiconductor structure SS may be used to strengthen the barrier effect between the gate structure GE and a gate dielectric layer, the problem that the gate dielectric layer is influenced by the diffusion of the material of the gate structure GE may be improved, the leakage current of the semiconductor device may be reduced, and the operation performance of the semiconductor device may be enhanced accordingly.

In some embodiments, the source structure SE, the semiconductor structure SS, the gate structure GE, and the barrier pattern 34P described above may be disposed on an upper surface 10 TS of the substrate 10. The upper surface 10TS and a lower surface 10BS of the substrate 10 may be two opposite surfaces of the substrate 10 in the vertical direction D1, and the vertical direction D1 may be regarded as a thickness direction of the substrate 10 accordingly, but not limited thereto. In this description, a distance between the upper surface 10TS of the substrate 10 and a relatively higher location and/or a relatively higher part in the vertical direction D1 may be greater than a distance between the upper surface 10TS of the substrate 10 and a relatively lower location and/or a relatively lower part in the vertical direction D1. The bottom or a lower portion of each component may be closer to the upper surface 10TS of the substrate 10 in the vertical direction D1 than the top or upper portion of this component. Another component disposed above a specific component may be regarded as being relatively far from the upper surface 10TS of the substrate 10 in the vertical direction D1, and another component disposed under a specific component may be regarded as being relatively close to the upper surface 10TS of the substrate 10 in the vertical direction D1. Additionally, in this description, an upper surface of a specific component may include the topmost surface of this component in the vertical direction D1, and a lower surface of a specific component may include the bottommost surface of this component in the vertical direction D1, but not limited thereto. In this description, the condition that a certain component is disposed between two other components in a specific direction may include a condition that the certain component is sandwiched between the two other components in the specific direction. The term “forming” or the term “disposing” are used in this description to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

In some embodiments, the semiconductor device 101 may further include a trench TR penetrating through the gate structure GE in the vertical direction D1, and at least a part of the semiconductor structure SS and at least a part of the barrier pattern 34P may be disposed in the trench TR. In some embodiments, the trench TR may include a first portion (such as a trench P1), a second portion (such as a trench P2), and a third portion (such as a trench P3) connected with one another. A bottom surface of the trench P2 may be lower than a bottom surface of the trench P1 in the vertical direction D1, and a bottom surface of the trench P3 may be lower than the bottom surface of the trench P2 in the vertical direction D1. In some embodiments, the semiconductor device 101 may further include a bottom semiconductor layer 18, a dielectric layer 20, a dielectric layer 26, a dielectric layer 28, and a dielectric layer 30. The bottom semiconductor layer 18 may be disposed between the source structure SE and the gate structure GE in the vertical direction D1. The dielectric layer 20 may be disposed between the bottom semiconductor layer 18 and the gate structure GE in the vertical direction D1. The dielectric layer 26 may be disposed on the dielectric layer 20 and surround the gate structure GE in the horizontal direction. The dielectric layer 28 may be disposed on the dielectric layer 26 and surround the gate structure GE in the horizontal direction. The dielectric layer 30 may cover the gate structure GE, the dielectric layer 28, and the dielectric layer 26 in the vertical direction D1. The trench P1 may penetrate through the dielectric layer 30 and the gate structure GE in the vertical direction D1, the trench P2 may be located in the dielectric layer 20, and the trench P3 may penetrate through the dielectric layer 20 and be connected with the bottom semiconductor layer 18. In some embodiments, at least a part of the semiconductor structure SS and at least a part of the barrier pattern 34P may be disposed in the trench P1.

In some embodiments, the semiconductor device 101 may further include a first gate dielectric layer 36, a second gate dielectric layer 32, and an insulation structure 42, and the semiconductor structure SS may include a semiconductor layer 38, a semiconductor layer 40, and a semiconductor layer 44. The first gate dielectric layer 36 may be disposed above the source structure SE and surround the semiconductor structure SS in the horizontal direction. The first gate dielectric layer 36 may be partly disposed between the semiconductor structure SS and the barrier pattern 34P in the horizontal direction, and an upper surface 34TS of the barrier pattern 34P may be lower than an upper surface 36TS of the first gate dielectric layer 36 in the vertical direction D1. The barrier pattern 34P may be disposed between the first gate dielectric layer 36 and the second gate dielectric layer 32 in the horizontal direction, and the barrier pattern 34P may directly contact the first gate dielectric layer 36 and the second gate dielectric layer 32, but not limited thereto. The second gate dielectric layer 32 may be disposed above the source structure SE and surround the semiconductor structure SS in the horizontal direction. The second gate dielectric layer 32 may be partly disposed between the first gate dielectric layer 36 and the gate structure GE in the horizontal direction, a part of the second gate dielectric layer 32 may be located between the barrier pattern 34P and the gate structure GE in the horizontal direction, and the upper surface 34TS of the barrier pattern 34P may be lower than an upper surface 32TS of the second gate dielectric layer 32 in the vertical direction D1. In some embodiments, the second gate dielectric layer 32 may be disposed in the trench P1, and the upper surface 32TS of the second gate dielectric layer 32 and an upper surface of the dielectric layer 30 may be substantially coplanar. The upper surface 32TS may be higher than an upper surface 24TS of the gate structure GE in the vertical direction D1, and a bottom of the second gate dielectric layer 32 may be connected with the dielectric layer 20. In addition, the first gate dielectric layer 36 may be disposed in the trench P1 and the trench P2. A part of the first gate dielectric layer 36 may be located above the barrier pattern 34P in the vertical direction D1, another part of the first gate dielectric layer 36 may be sandwiched between the semiconductor structure SS and the dielectric layer 20 in the vertical direction D1, and the upper surface 36TS of the first gate dielectric layer 36 and the upper surface 32TS of the second gate dielectric layer 32 may be substantially coplanar, but not limited thereto.

The semiconductor layer 38 in the semiconductor structure SS may be disposed on and directly contact the first gate dielectric layer 36, the semiconductor layer 40 may be partly disposed on the semiconductor layer 38, and the semiconductor layer 40 may be partly disposed in the trench P3 for being connected with the bottom semiconductor layer 18. The insulation structure 42 may be disposed in the trench TR, and the semiconductor layer 40 may surround the insulation structure 42 in the horizontal direction. The semiconductor layer 44 may be disposed on the insulation structure 42, and the insulation structure 42 may be sandwiched between the semiconductor layer 44 and the semiconductor layer 40 in the vertical direction D1. In some embodiments, a top surface of the semiconductor layer 38, a top surface of the semiconductor layer 40, and a top surface of the semiconductor layer 44 may be substantially coplanar, and the semiconductor structure SS may include a ladder-shaped structure LS located on the barrier pattern 34P because of the influence of the barrier pattern 34P. For instance, the ladder-shaped structure LS may be composed of the semiconductor layer 38 and the semiconductor layer 40 stacked on the barrier pattern 34P and the first gate dielectric layer 36. In some embodiments, the upper surface 34TS of the barrier pattern 34P and the upper surface 24TS of the gate structure GE may be substantially coplanar or the upper surface 34TS of the barrier pattern 34P is higher than the upper surface 24TS of the gate structure GE in the vertical direction D1, and a length L2 of the barrier pattern 34P in the vertical direction D1 may be greater than or equal to a length L1 of the gate structure GE in the vertical direction D1 for ensuring that the required barrier effect may be provided by the barrier pattern 34P.

In some embodiments, the semiconductor device 101 may further include a drain structure DE, a sidewall structure 50, and a dielectric layer 52. The dielectric layer 52 may be disposed on the dielectric layer 30, the drain structure DE may be disposed on the second gate dielectric layer 32, the first gate dielectric layer 36, and the semiconductor structure SS, and the sidewall structure 50 may be disposed on a sidewall of the drain structure DE. In some embodiments, the semiconductor device 101 may include a plurality of the gate structures GE and the components located corresponding to the gate structures GE, such as the second gate dielectric layers 32, the barrier patterns 34P, the first gate dielectric layers 36, the semiconductor structures SS, the insulation structures 42, and the drain structures DE, and the source structure SE may be connected with the semiconductor structures SS, but not limited thereto.

In some embodiments, the source structure SE, the gate structure GE, and the drain structure DE may be respectively made of layers of electrically conductive materials. For example, the source structure SE may include a barrier layer 12, a barrier layer 16, and an electrically conductive layer disposed between the barrier layer 12 and the barrier layer 16 in the vertical direction D1; the gate structure GE may include a barrier layer 22 and an electrically conductive layer 24 disposed on the barrier layer 22 in the vertical direction D1; and the drain structure DE may include a barrier layer 46 and an electrically conductive layer 48 disposed on the barrier layer 46 in the vertical direction D1, but not limited thereto. The barrier layer 12, the barrier layer 16, the barrier layer 22, the barrier layer 46, and the barrier pattern 34P described above may include titanium nitride, tantalum nitride, or other suitable electrically conductive barrier materials, and the material compositions of the barrier layer 12, the barrier layer 16, the barrier layer 22, the barrier layer 46, and the barrier pattern 34P may be identical to or different from one another. The electrically conductive layer 14, the electrically conductive layer 24, and the electrically conductive layer 48 may include copper, aluminum, tungsten, or other electrically conductive materials with low electrical resistivity, and the material compositions of the electrically conductive layer 14, the electrically conductive layer 24, and the electrically conductive layer 48 may be identical to or different from one another. In addition, the semiconductor layer 38, the semiconductor layer 40, and the semiconductor layer 44 in the semiconductor structure SS and the bottom semiconductor layer 18 may include silicon-containing semiconductor materials (such as polysilicon semiconductor material or amorphous silicon semiconductor material, but not limited thereto), oxide semiconductor materials (such as indium gallium zinc oxide semiconductor material, but not limited thereto), or other suitable semiconductor materials. The material composition of the semiconductor layer 38, the semiconductor layer 40, the semiconductor layer 44, and the bottom semiconductor layer 18 may be identical to or different from one another.

In some embodiments, the dielectric layer 20, the dielectric layer 26, the dielectric layer 28, the dielectric layer 30, and the dielectric layer 52 may include an oxide dielectric material (such as silicon oxide, but not limited thereto), a nitride dielectric material (such as silicon nitride, but not limited thereto), tetraethoxysilane (TEOS), or other suitable dielectric materials. The material composition of the first gate dielectric layer 36 may be different from the material composition of the second gate dielectric layer 32. The second gate dielectric layer 32 may include a nitride dielectric material (such as silicon nitride, but not limited thereto), and the first gate dielectric layer 36 may include an oxide dielectric material (such as silicon oxide, but not limited thereto), a high dielectric constant dielectric material (such as a dielectric material with dielectric constant higher than 3.9 or 4.52), or other suitable dielectric materials. The insulation structure 42 may include an oxide insulation material (such as silicon oxide, but not limited thereto) or other suitable insulation materials, and the sidewall structure 50 may include a nitride dielectric material (such as silicon nitride, but not limited thereto) or other suitable dielectric materials.

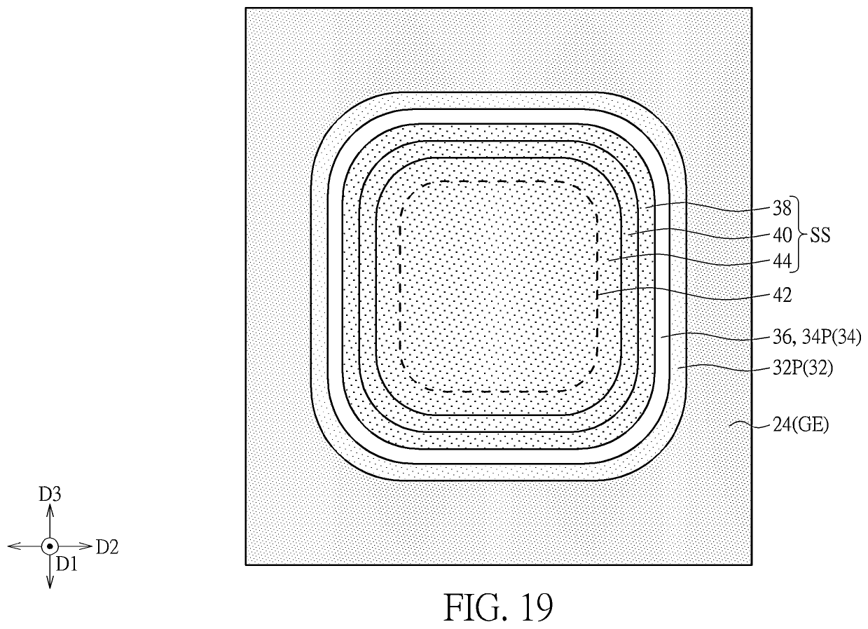

Please refer to FIG. 1 and FIG. 19. FIG. 19 is a top view schematic drawing illustrating a portion of a semiconductor device according to an embodiment of the present invention. In some embodiments, FIG. 19 may be regarded as a top view schematic drawing illustrating a portion of the semiconductor device 101 described above, but not limited thereto. As shown in FIG. 1 and FIG. 19, in some embodiments, the second gate dielectric layer 32, the barrier pattern 34P, the first gate dielectric layer 36, the semiconductor layer 38, the semiconductor layer 40, and the insulation structure 42 may be columnar structures extending in the vertical direction D1, respectively, and central axes of the columnar structures extending in the vertical direction D1 may substantially overlap one another when viewed in the vertical direction D1, but not limited thereto. Therefore, in the top view diagram of the semiconductor device 101, the gate structure GE may surround the second gate dielectric layer 32, the barrier pattern 34P, the first gate dielectric layer 36, the semiconductor structure SS, and the insulation structure 42 located in the trench TR in the horizontal direction (such as the horizontal direction D2, the horizontal direction D3, and/or other horizontal directions substantially orthogonal to the vertical direction D1); the second gate dielectric layer 32 may surround the barrier pattern 34P, the first gate dielectric layer 36, the semiconductor structure SS, and the insulation structure 42 in the horizontal direction; and the barrier pattern 34P may surround the first gate dielectric layer 36, the semiconductor structure SS, and the insulation structure 42 in the horizontal direction. The semiconductor structure SS may surround the insulation structure 42 in the top view diagram and the cross-sectional diagram of the semiconductor device 101. It is worth noting that the shape of the trench TR in the top view diagram of the semiconductor device according to the present invention is not limited to the condition illustrated in FIG. 19 and the trench TR with other shapes may be applied also according to some design considerations.

In some embodiments, the substrate 10 may include a base layer (not illustrated) and a dielectric layer disposed on the base layer. The base layer may include a semiconductor substrate such as a silicon substrate, a silicon germanium semiconductor substrate, a silicon-on-insulator (SOI) substrate, or a substrate made of other suitable materials. In addition, other devices (such as transistors) and/or circuits (not illustrated) may be formed on the base layer described above, and the semiconductor device 101 may be electrically connected downward and/or upward to other devices and/or circuits on the base layer. In some embodiments, the manufacturing method of the semiconductor device 101 may be integrated with the back end of line (BEOL) process in the semiconductor manufacturing process, and the semiconductor device 101 may be regarded as a vertical transistor structure including a gate surrounding a semiconductor layer in the horizontal directions, but not limited thereto.

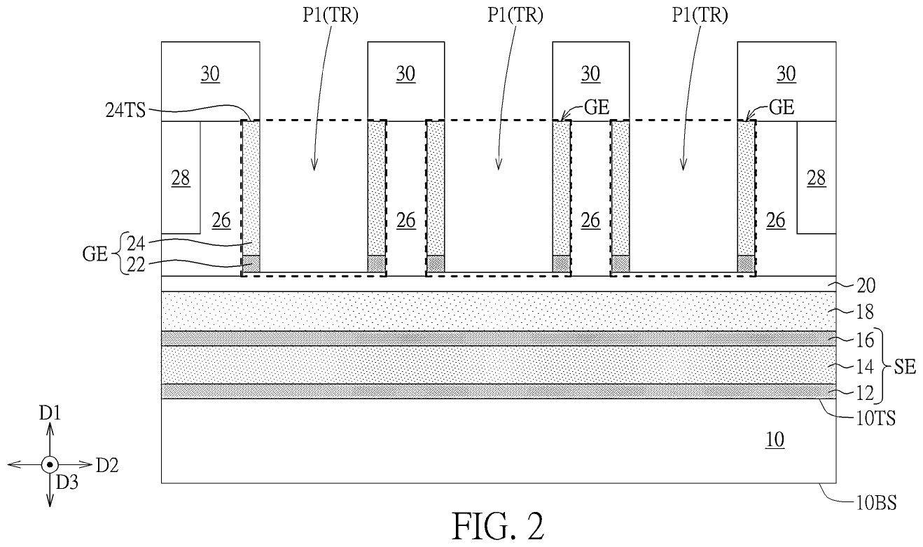

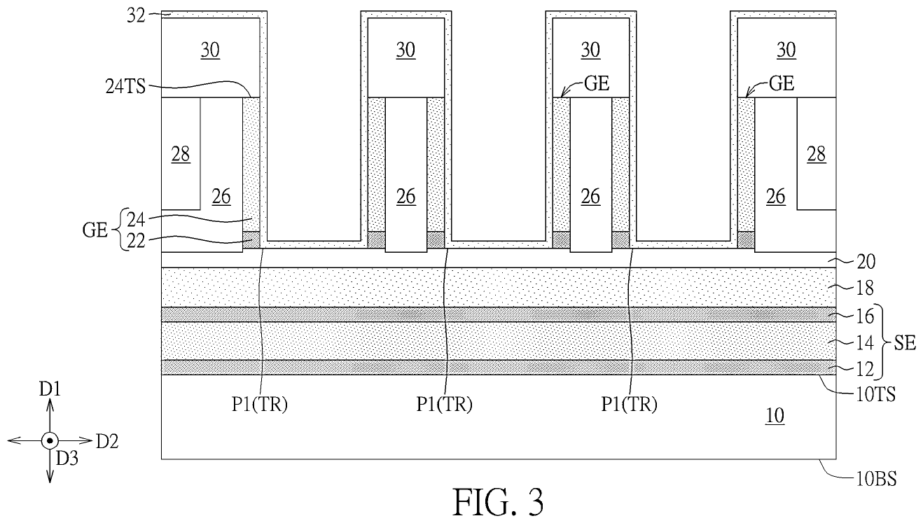

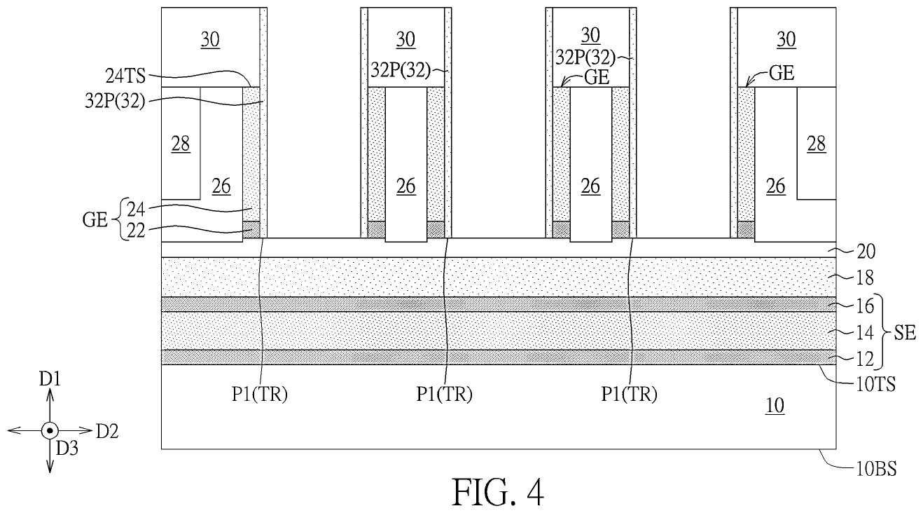

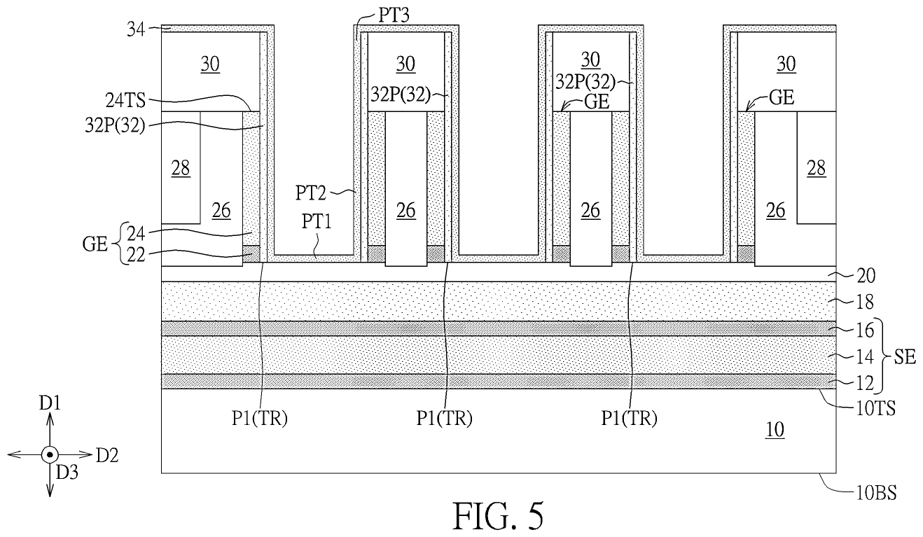

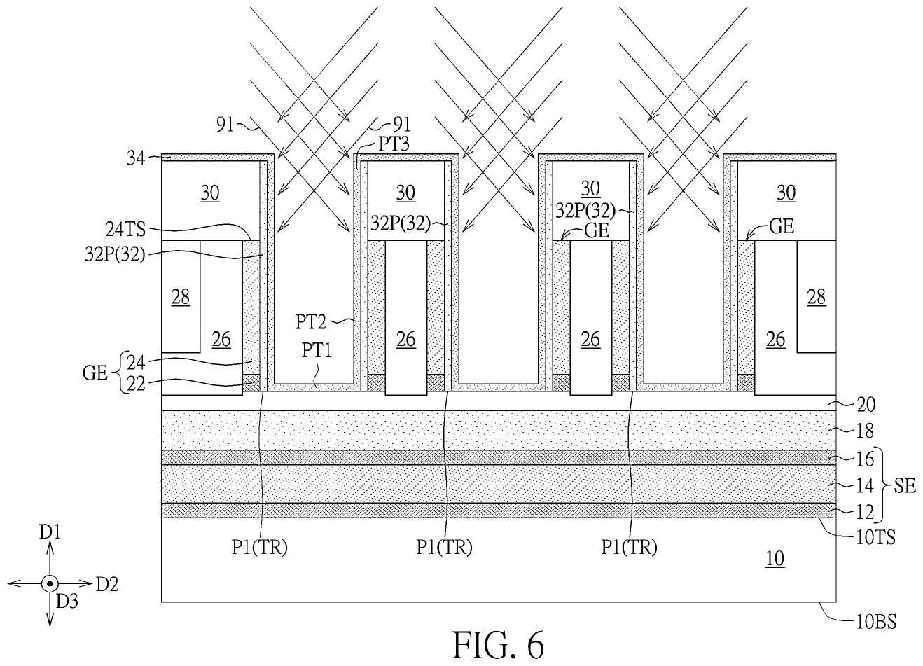

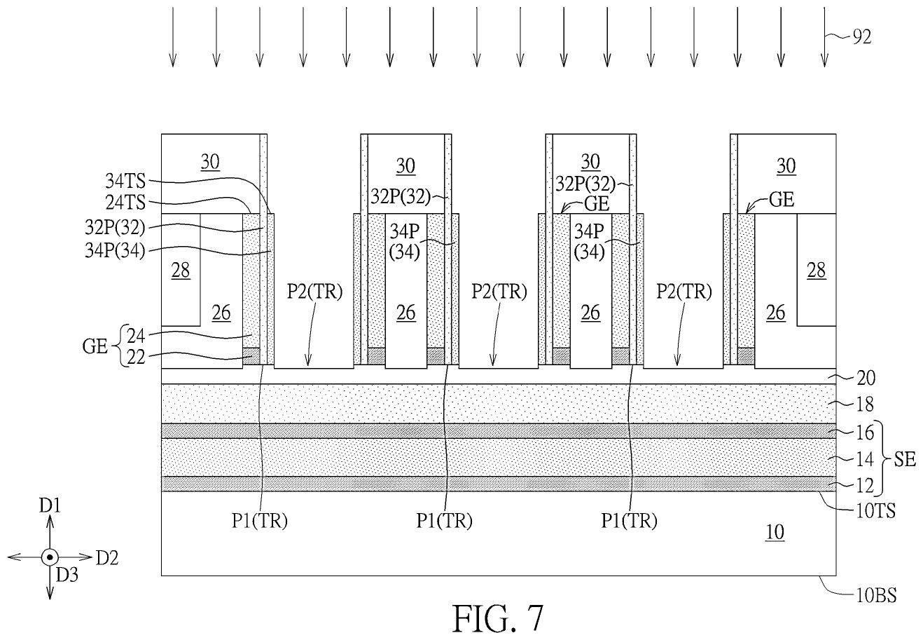

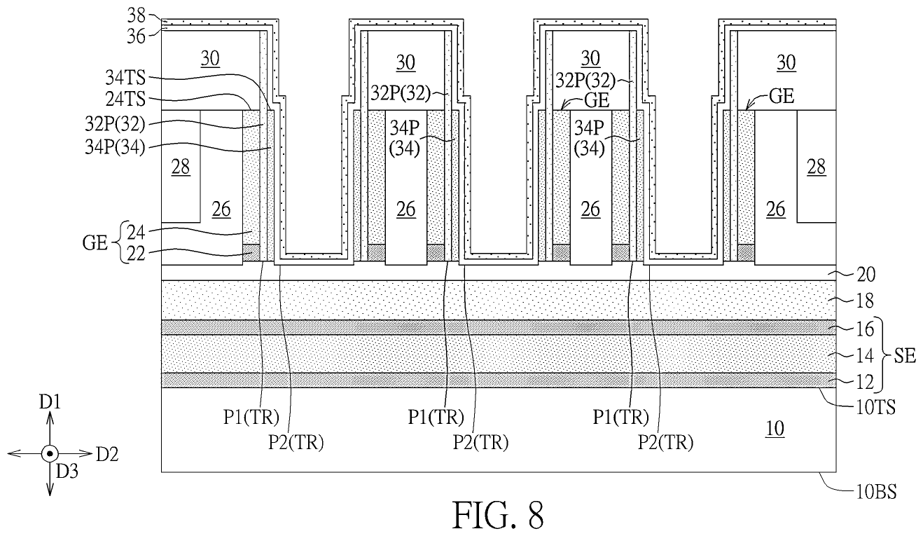

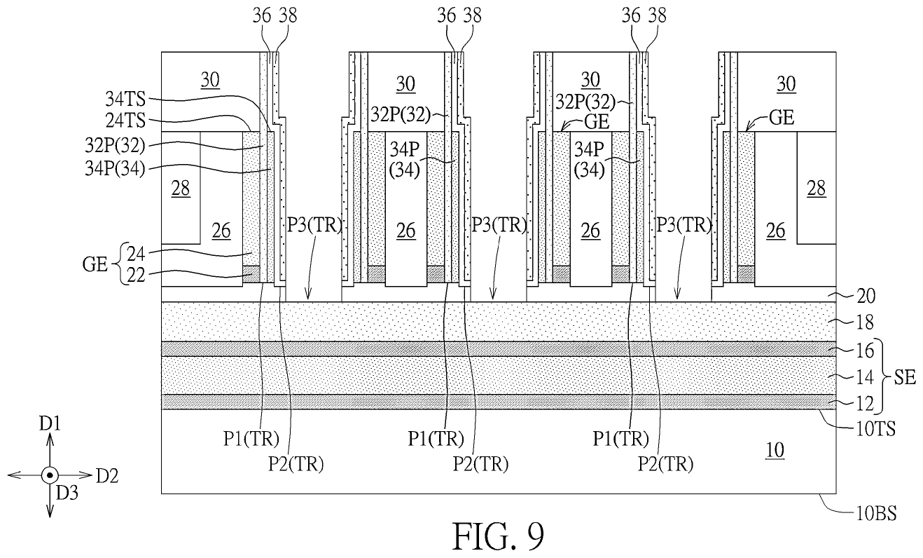

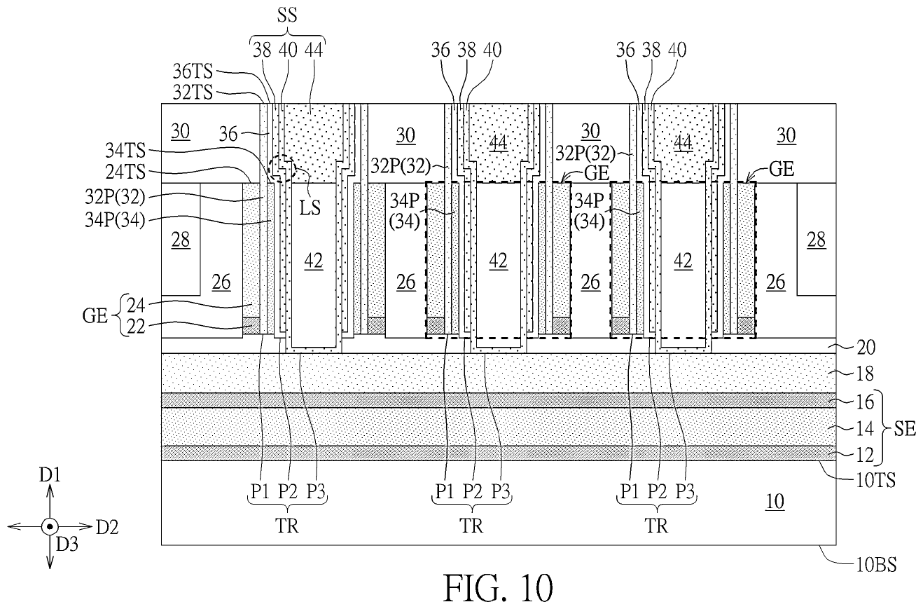

Please refer to FIG. 1 and FIGS. 2-10. FIGS. 2-10 are schematic drawings illustrating a manufacturing method of a semiconductor device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, and FIG. 10 is a schematic drawing in a step subsequent to FIG. 9. In some embodiments, FIG. 1 may be regarded as a schematic drawing in a step subsequent to FIG. 10, but not limited thereto. As shown in FIG. 1, the manufacturing method of the semiconductor device in this embodiment may include the following steps. The substrate 10 is provided, and the source structure SE is formed above the substrate 10. The gate structure GE is formed above the source structure SE in the vertical direction D1. The barrier pattern 34P is formed above the source structure SE, and the gate structure GE surrounds the barrier pattern 34P in the horizontal direction. The semiconductor structure SS is formed above the source structure SE, and the gate structure GE surrounds the semiconductor structure SS in the horizontal direction. The barrier pattern 34P surrounds the semiconductor structure SS in the horizontal direction, and the barrier pattern 34P is located between the gate structure GE and the semiconductor structure SS in the horizontal direction.

Specifically, the manufacturing method of the semiconductor device in this embodiment may include but is not limited to the following steps. As shown in FIG. 2, the source structure SE, the bottom semiconductor layer 18, the dielectric layer 20, the gate structure GE, the dielectric layer 26, the dielectric layer 28, and the dielectric layer 30 may be formed sequentially on the upper surface 10TS of the substrate 10. Subsequently, the trench is formed penetrating through the dielectric layer 30 and the gate structure GE in the vertical direction D1 for exposing a part of the dielectric layer 20. In some embodiments, the dielectric layer 26 and/or the dielectric layer 28 may be located between the gate structures GE adjacent to each other.

As shown in FIG. 3, the second gate dielectric layer 32 may then be formed, and the second gate dielectric layer 32 may be formed conformally on the bottom and the sidewall of the trench P1 and conformally on the dielectric layer 30. Therefore, the second gate dielectric layer 32 may be partly formed in the trench P1 and partly formed outside the trench P1. As shown in FIG. 3 and FIG. 4, an etching back process may be performed to the second gate dielectric layer 32 for removing the second gate dielectric layer 32 located above the dielectric layer 30 in the vertical direction D1 and a part of the second gate dielectric layer 32 located at the bottom of the trench P1, so as to expose the dielectric layer 20 and form a dielectric pattern 32P, and the dielectric pattern 32P may be located on a sidewall of the trench P1. Subsequently, as shown in FIG. 5, a barrier layer 34 may be formed above the source structure SE, and the barrier layer 34 may be partly formed in the trench P1 and partly formed outside the trench P1. The barrier layer 34 may be formed conformally on the bottom of the trench P1, on the second gate dielectric layer (i.e. the dielectric pattern 32P), and on the dielectric layer 30, and the barrier layer 34 may cover the dielectric pattern 32P located in the trench P1. In some embodiments, the barrier layer 34 may include a first portion PT1, a second portion PT2, and a third portion PT3. The first portion PT1 is located on the bottom of the trench P1, the second portion PT2 is located on a lower part of the sidewall of the trench P1 and connected with the first portion PT1, and the third portion PT3 is partly located on an upper part of the sidewall of the trench P1 and connected with the second portion PT2. In addition, the third portion PT3 may be further partly located on the dielectric layer 30 in the vertical direction D1.

As shown in FIG. 6, a tilted ion implantation process 91 may be performed to the third portion PT3 of the barrier layer 34, and the influence of the tilted ion implantation process 91 on the second portion PT2 may be avoided and/or reduced by controlling the ion implantation angle of the tilted ion implantation process 91. An ion used in the tilted ion implantation process 91 may include an arsenic ion, a xenon ion, or other suitable ions for generating amorphous effect to the third portion PT3 of the barrier layer 34 and changing the etching property of the third portion PT3 of the barrier layer 34 (such as increasing the etching rate to the third portion PT3 of the barrier layer 34, but not limited thereto). As shown in FIG. 6 and FIG. 7, an etching process 92 may be performed after the tilted ion implantation process 91 for removing the first portion PT1 and the third portion PT3 of the barrier layer 34, and the barrier layer 34 remains in the trench P1 after the etching process 92 becomes the barrier pattern 34P. Therefore, in this embodiment, the second gate dielectric layer 32 (i.e. the dielectric pattern 32P) is formed before the step of forming the barrier pattern 34P. In some embodiments, the etching process 92 may include an anisotropic etching approach (such as anisotropic dry etching) or other suitable etching approaches. By controlling the process parameters of the tilted ion implantation process 91 and/or the etching process 92, the upper surface 34TS of the barrier pattern 34P and the upper surface 24TS of the gate structure GE may be substantially coplanar or the upper surface 34TS of the barrier pattern 34P is higher than the upper surface 24TS of the gate structure GE in the vertical direction D1 for ensuring that the required barrier effect may be provided by the barrier pattern 34P. In addition, a part of the dielectric layer 20 may be removed by the etching process 92 for forming the trench P2, and the bottom surface of the trench P2 may be lower than the bottom surface of the barrier pattern 34P and the bottom surface of the dielectric pattern 32P in the vertical direction D1 accordingly. It is worth noting that, in the manufacturing method according to the present invention, the method of forming the barrier pattern 34P may include but is not limited to the steps illustrated in FIGS. 5-7 described above. In other words, the barrier pattern 34P may be formed by other approaches according to some design considerations.

As shown in FIG. 8, after the step of forming the barrier pattern 34P, the first gate dielectric layer 36 and the semiconductor layer 38 may be formed. The first gate dielectric layer 36 may be formed conformally on the dielectric layer 30, the dielectric pattern 32P, the barrier pattern 34P, and the dielectric layer 20. The first gate dielectric layer 36 may be partly formed in the trench P2, partly formed in the trench P1, and partly formed outside the trench P1 and the trench P2. The semiconductor layer 38 may be formed conformally on the first gate dielectric layer 36, and the semiconductor layer 38 may be partly formed in the trench P1 and partly formed outside the trench P1. Subsequently, as shown in FIG. 8 and FIG. 9, an etching back process may be performed to the semiconductor layer 38 and the first gate dielectric layer 36 for removing the semiconductor layer 38 and the first gate dielectric layer 36 located outside the trench P2 and the trench Pl and removing at least a part of the semiconductor layer 38 and the first gate dielectric layer 36 located at the bottom of the trench P2 and the bottom of the trench P1, so as to form the trench P3 penetrating through the dielectric layer 20 and form the trench TR described above accordingly. As shown in FIG. 10, the semiconductor layer 40, the insulation structure 42, and the semiconductor layer 44 may then be formed in the trench TR, and the semiconductor structure SS may be formed accordingly. In other words, in this embodiment, the first gate dielectric layer 36 and the second gate dielectric layer 32 may be formed above the source structure SE before the semiconductor structure SS is formed. The first gate dielectric layer 36 may surround the semiconductor structure SS in the horizontal direction, the first gate dielectric layer 36 may be partly located between the semiconductor structure SS and the barrier pattern 34P in the horizontal direction, and the upper surface 34TS of the barrier pattern 34P may be lower than the upper surface 36TS of the first gate dielectric layer 36 in the vertical direction D1. In addition, the second gate dielectric layer 32 may surround the semiconductor structure SS in the horizontal direction, the second gate dielectric layer 32 may be partly located between the first gate dielectric layer 36 and the gate structure GE in the horizontal direction, and the upper surface 34TS of the barrier pattern 34P may be lower than the upper surface 32TS of the second gate dielectric layer 32 in the vertical direction D1. In some embodiments, the semiconductor layer 40 and the semiconductor layer 44 may be formed partly in the trench TR and formed partly outside the trench TR, and a planarization process may be performed for removing the material layers located outside the trench TR and forming the semiconductor layer 40 and the semiconductor layer 44 illustrated in FIG. 10. Therefore, the upper surface of the dielectric layer 30, the upper surface 32TS of the second gate dielectric layer 32, the upper surface 36TS of the first gate dielectric layer 36, the upper surface of the semiconductor layer 38, the upper surface of the semiconductor layer 40, and the upper surface of the semiconductor layer 44 may be substantially coplanar, but not limited thereto. Subsequently, as shown in FIG. 1, the drain structure DE, the sidewall structure 50, and the dielectric layer 52 may be formed for forming the semiconductor device 101.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

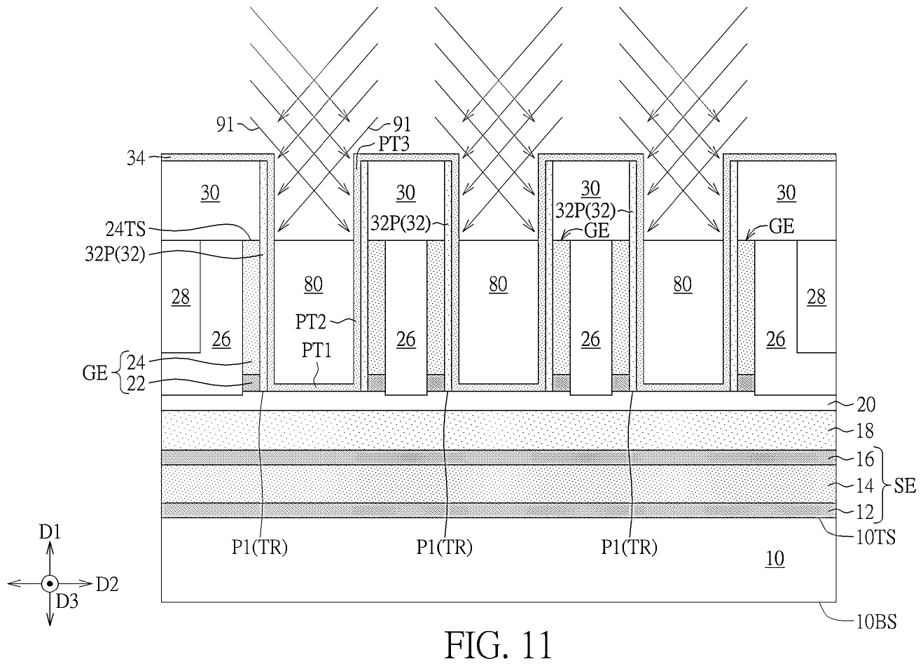

Please refer to FIG. 11 and FIG. 7. FIG. 11 is a schematic drawing illustrating a manufacturing method of a semiconductor device according to another embodiment of the present invention. In some embodiments, FIG. 7 may be regarded as a schematic drawing in a step subsequent to FIG. 11, but not limited thereto. As shown in FIG. 11, in the manufacturing method of the semiconductor device according to this embodiment, a mask layer 80 may be formed in the trench P1 before the tilted ion implantation process 91, and the mask layer 80 covers the first portion PT1 and the second portion PT2 of the barrier layer 34 in the tilted ion implantation process 91 for avoiding and/or reducing the influence of the tilted ion implantation process 91 on the second portion PT2 of the barrier layer 34. As shown in FIG. 11 and FIG. 7, after the tilted ion implantation process 91 and before the etching process 92, the mask layer 80 may be removed, and the barrier pattern 34P and the trench P2 may be formed by the etching process 92. In some embodiments, the mask layer 80 may include spin on dielectric (SOD) or other suitable mask materials.

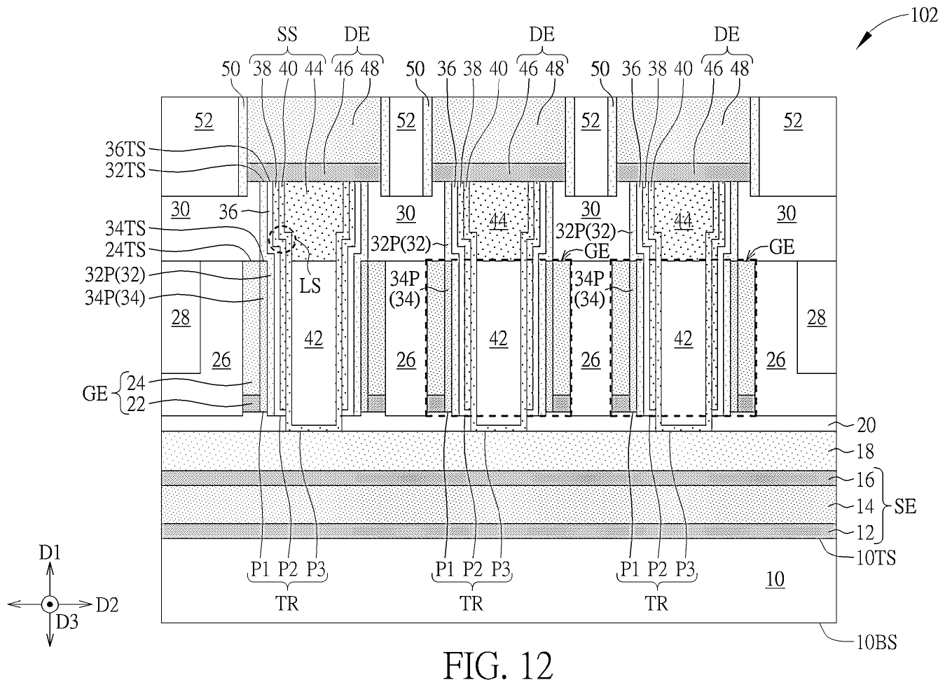

Please refer to FIG. 12. FIG. 12 is a cross-sectional schematic drawing illustrating a semiconductor device 102 according to a second embodiment of the present invention. As shown in FIG. 12, in the semiconductor device 102, the barrier pattern 34P may be located between the second gate dielectric layer 32 and the gate structure GE in the horizontal direction, and the barrier pattern 34P may directly contact the second gate dielectric layer 32 and the gate structure GE, but not limited thereto. In addition, a part of the second gate dielectric layer 32 may be located above the barrier pattern 34P in the vertical direction D1, and the second gate dielectric layer 32 may cover the upper surface 34TS of the barrier pattern 34P in the vertical direction DI.

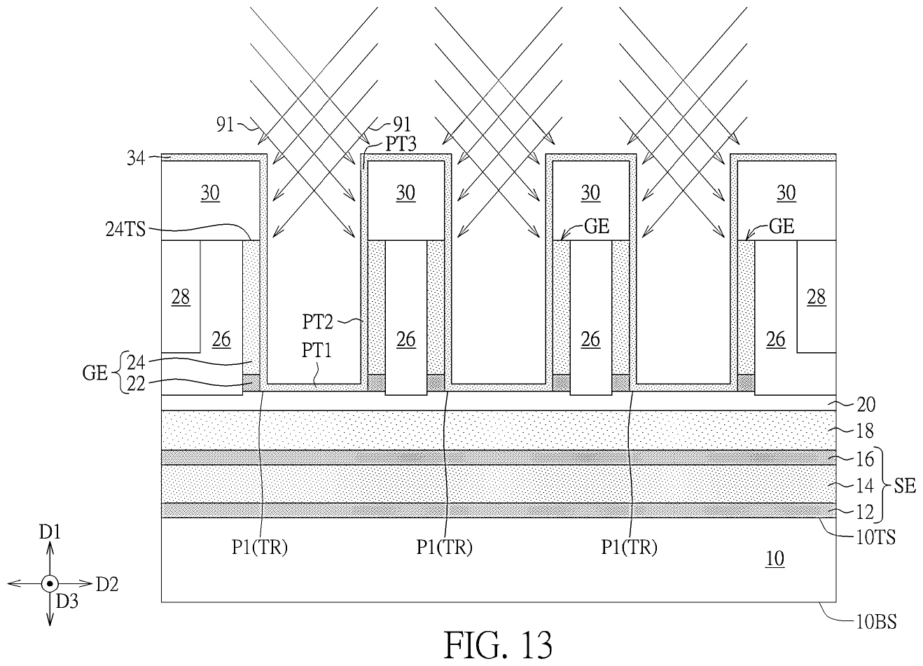

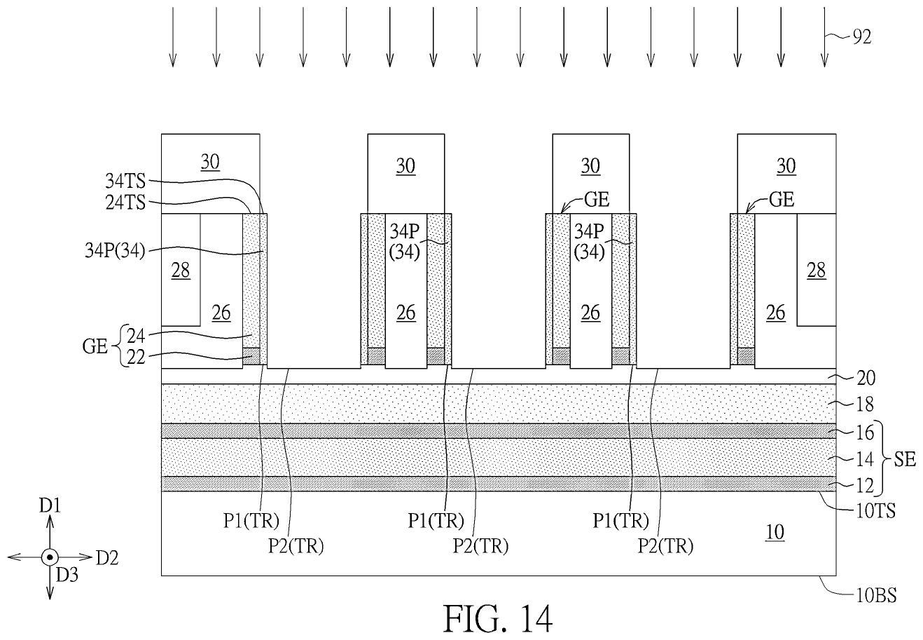

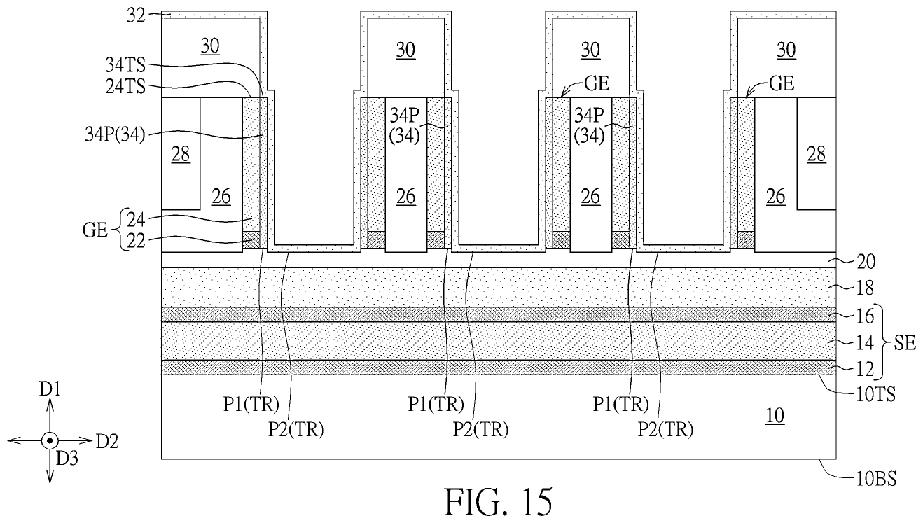

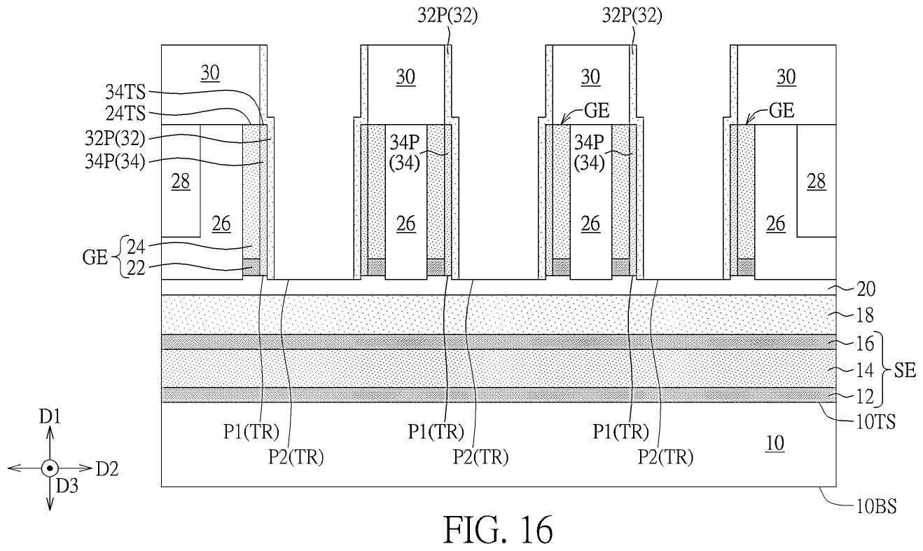

Please refer to FIGS. 13-16 and FIG. 12. FIGS. 13-16 are schematic drawings illustrating a manufacturing method of a semiconductor device according to an embodiment of the present invention, wherein FIG. 14 is a schematic drawing in a step subsequent to FIG. 13, FIG. 15 is a schematic drawing in a step subsequent to FIG. 14, and FIG. 16 is a schematic drawing in a step subsequent to FIG. 15. In some embodiments, FIG. 12 may be regarded as a schematic drawing in a step subsequent to FIG. 16, but not limited thereto. As shown in FIG. 13, in the manufacturing method of the semiconductor device according to this embodiment, the barrier layer 34 may be formed above the source structure SE, the barrier layer 34 may be partly formed in the trench P1 and partly formed outside the trench P1, and the barrier layer 34 may be formed conformally on the bottom of the trench P1, the sidewall of the trench P1, and the dielectric layer 30. Subsequently, the tilted ion implantation process 91 may be performed to the third portion PT3 of the barrier layer 34, and the influence of the tilted ion implantation process 91 on the second portion PT2 may be avoided and/or reduced by controlling the ion implantation angle of the tilted ion implantation process 91. As shown in FIG. 13 and FIG. 14, the etching process 92 may be performed after the tilted ion implantation process 91 for removing the first portion PT1 and the third portion PT3 of the barrier layer 34, and the barrier layer 34 remains in the trench P1 after the etching process 92 becomes the barrier pattern 34P. In some embodiments, a part of the dielectric layer 20 may be removed by the etching process 92 for forming the trench P2, but not limited thereto. As shown in FIG. 15, the second gate dielectric layer 32 may be formed after the step of forming the barrier pattern 34P. The second gate dielectric layer 32 may be formed conformally on the bottom of the trench P2, the barrier pattern 34P, and the dielectric layer 30, and the second gate dielectric layer 32 may cover the barrier pattern 34P located in the trench P1. Therefore, the second gate dielectric layer 32 may be partly formed in the trench P1 and the trench P2 and partly formed outside the trench P1 and the trench P2. As shown in FIG. 15 and FIG. 16, an etching back process may be performed to the second gate dielectric layer 32 for removing the second gate dielectric layer 32 located above the dielectric layer 30 in the vertical direction D1 and a part of the second gate dielectric layer 32 located at the bottom of the trench P2, so as to expose the dielectric layer 20 and form the dielectric pattern 32P. Subsequently, as shown in FIG. 16 and FIG. 12, the first gate dielectric layer 36, the semiconductor structure SS, the insulation structure 42, the drain structure DE, the sidewall structure 50, and the dielectric layer 50 may be formed for forming the semiconductor device 102.

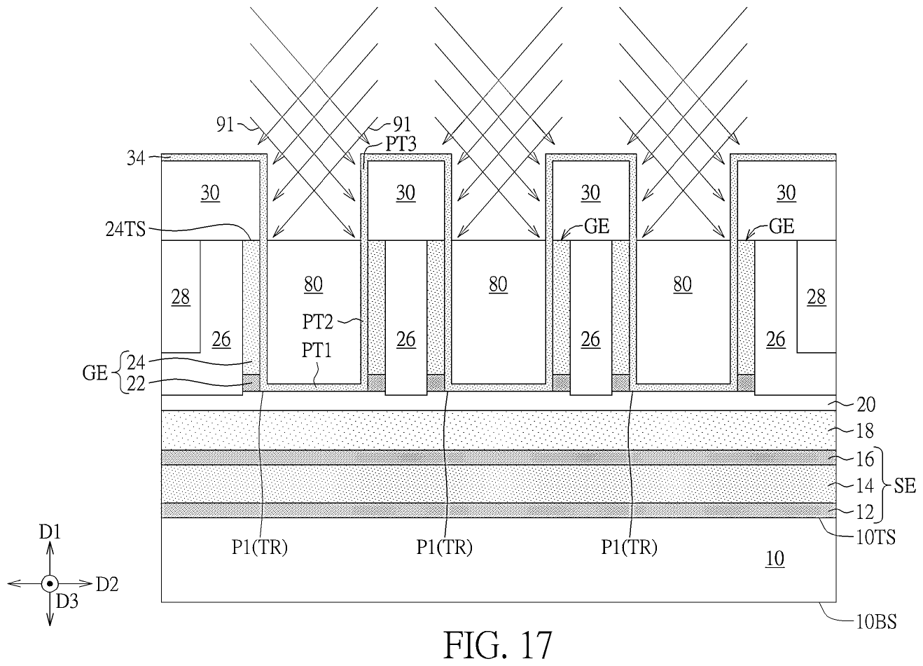

Please refer to FIG. 17 and FIG. 14. FIG. 17 is a schematic drawing illustrating a manufacturing method of a semiconductor device according to another embodiment of the present invention. In some embodiments, FIG. 14 may be regarded as a schematic drawing in a step subsequent to FIG. 17, but not limited thereto. As shown in FIG. 17, in the manufacturing method of the semiconductor device according to this embodiment, the mask layer 80 may be formed in the trench P1 before the tilted ion implantation process 91, and the mask layer 80 covers the first portion PT1 and the second portion PT2 of the barrier layer 34 in the tilted ion implantation process 91 for avoiding and/or reducing the influence of the tilted ion implantation process 91 on the second portion PT2 of the barrier layer 34. As shown in FIG. 17 and FIG. 14, after the tilted ion implantation process 91 and before the etching process 92, the mask layer 80 may be removed, and the barrier pattern 34P and the trench P2 may be formed by the etching process 92.

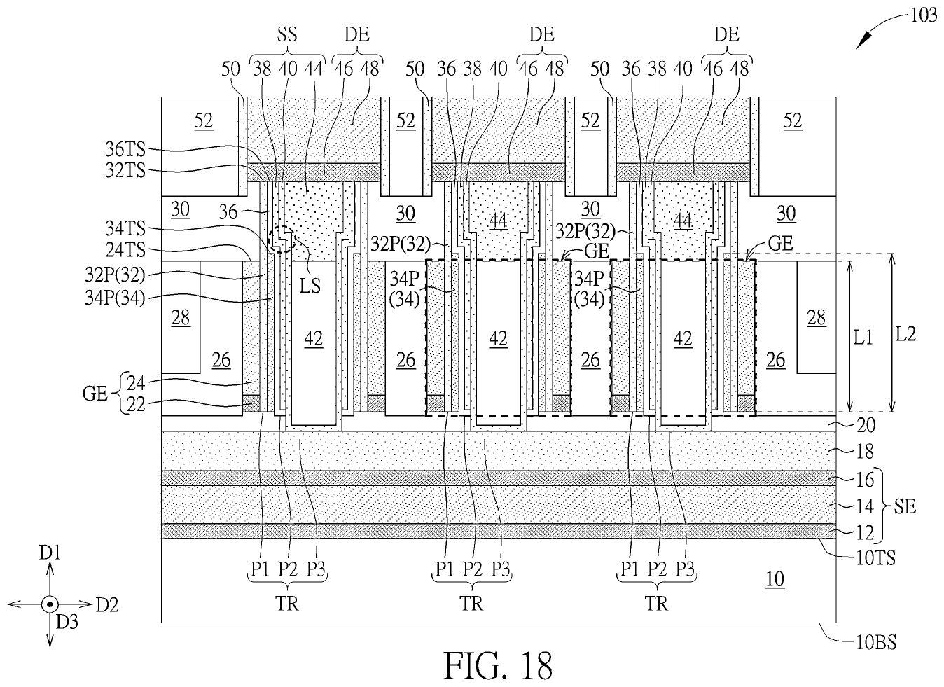

Please refer to FIG. 18. FIG. 18 is a cross-sectional schematic drawing illustrating a semiconductor device 103 according to a third embodiment of the present invention. As shown in FIG. 18, in the semiconductor device 103, the upper surface 34 of the barrier pattern 34P may be higher than the upper surface 24TS of the gate structure GE in the vertical direction D1, and the length L2 of the barrier pattern 34P in the vertical direction DI may be greater than the length L1 of the gate structure GE in the vertical direction D1 for ensuring that the required barrier effect may be provided by the barrier pattern 34P.

To summarize the above descriptions, in the semiconductor device and the manufacturing method thereof according to the present invention, the barrier pattern is disposed between the gate structure and the semiconductor structure for strengthen the barrier effect between the gate structure and the gate dielectric layer. The problem that the gate dielectric layer is influenced by the diffusion of the material of the gate structure may be improved, the leakage current of the semiconductor device may be reduced, and the operation performance of the semiconductor device may be enhanced accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a source structure disposed on the substrate;
a semiconductor structure disposed above the source structure in a vertical direction;
a gate structure disposed above the source structure and surrounding the semiconductor structure in a horizontal direction; and
a barrier pattern disposed between the gate structure and the semiconductor structure in the horizontal direction, wherein the gate structure surrounds the barrier pattern in the horizontal direction, and the barrier pattern surrounds the semiconductor structure in the horizontal direction.

2. The semiconductor device according to claim 1, further comprising:
a trench penetrating through the gate structure in the vertical direction, and at least a part of the semiconductor structure and at least a part of the barrier pattern are disposed in the trench.

3. The semiconductor device according to claim 1, wherein the semiconductor structure comprises a ladder-shaped structure located on the barrier pattern.

4. The semiconductor device according to claim 1, wherein an upper surface of the barrier pattern and an upper surface of the gate structure are coplanar or the upper surface of the barrier pattern is higher than the upper surface of the gate structure in the vertical direction.

5. The semiconductor device according to claim 1, wherein a length of the barrier pattern in the vertical direction is greater than or equal to a length of the gate structure in the vertical direction.

6. The semiconductor device according to claim 1, further comprising:
a first gate dielectric layer disposed above the source structure and surrounding the semiconductor structure in the horizontal direction, wherein the first gate dielectric layer is partly disposed between the semiconductor structure and the barrier pattern in the horizontal direction, and an upper surface of the barrier pattern is lower than an upper surface of the first gate dielectric layer in the vertical direction.

7. The semiconductor device according to claim 6, further comprising:
a second gate dielectric layer disposed above the source structure and surrounding the semiconductor structure in the horizontal direction, wherein the second gate dielectric layer is partly disposed between the first gate dielectric layer and the gate structure in the horizontal direction, and the upper surface of the barrier pattern is lower than an upper surface of the second gate dielectric layer in the vertical direction.

8. The semiconductor device according to claim 7, wherein a part of the second gate dielectric layer is located between the barrier pattern and the gate structure in the horizontal direction.

9. The semiconductor device according to claim 7, wherein the barrier pattern is located between the second gate dielectric layer and the gate structure in the horizontal direction.

10. The semiconductor device according to claim 1, wherein the barrier pattern comprises titanium nitride or tantalum nitride.

11. A manufacturing method of a semiconductor device, comprising:
providing a substrate;
forming a source structure above the substrate;
forming a gate structure above the source structure in a vertical direction;
forming a barrier pattern above the source structure, wherein the gate structure surrounds the barrier pattern in a horizontal direction; and
forming a semiconductor structure above the source structure, wherein the gate structure surrounds the semiconductor structure in the horizontal direction, the barrier pattern surrounds the semiconductor structure in the horizontal direction, and the barrier pattern is located between the gate structure and the semiconductor structure in the horizontal direction.

12. The manufacturing method of the semiconductor device according to claim 11, further comprising:
forming a trench penetrating through the gate structure in the vertical direction before the barrier pattern is formed, wherein at least a part of the semiconductor structure and at least a part of the barrier pattern are disposed in the trench.

13. The manufacturing method of the semiconductor device according to claim 11, wherein a method of forming the barrier pattern comprises:
forming a barrier layer above the source structure, wherein the barrier layer comprises:
a first portion located on a bottom of the trench;
a second portion located on a lower part of a sidewall of the trench and connected with the first portion; and
a third portion located on an upper part of the sidewall of the trench and connected with the second portion;
performing a tilted ion implantation process to the third portion of the barrier layer; and
performing an etching process for removing the first portion and the third portion of the barrier layer, wherein the barrier layer remains in the trench after the etching process becomes the barrier pattern.

14. The manufacturing method of the semiconductor device according to claim 13, wherein an ion used in the tilted ion implantation process comprises an arsenic ion or a xenon ion.

15. The manufacturing method of the semiconductor device according to claim 13, wherein the method of forming the barrier pattern further comprises:
forming a mask layer in the trench before the tilted ion implantation process, wherein the mask layer covers the first portion and the second portion of the barrier layer in the tilted ion implantation process; and
removing the mask layer before the etching process.

16. The manufacturing method of the semiconductor device according to claim 11, further comprising:
forming a first gate dielectric layer above the source structure before the semiconductor structure is formed, wherein the first gate dielectric layer surrounds the semiconductor structure in the horizontal direction, the first gate dielectric layer is partly located between the semiconductor structure and the barrier pattern in the horizontal direction, and an upper surface of the barrier pattern is lower than an upper surface of the first gate dielectric layer in the vertical direction.

17. The manufacturing method of the semiconductor device according to claim 16, further comprising:
forming a second gate dielectric layer above the source structure before the semiconductor structure is formed, wherein the second gate dielectric layer surrounds the semiconductor structure in the horizontal direction, the second gate dielectric layer is partly located between the first gate dielectric layer and the gate structure in the horizontal direction, and the upper surface of the barrier pattern is lower than an upper surface of the second gate dielectric layer in the vertical direction.

18. The manufacturing method of the semiconductor device according to claim 17, wherein the second gate dielectric layer is formed before the barrier pattern is formed.

19. The manufacturing method of the semiconductor device according to claim 17, wherein the second gate dielectric layer is formed after the barrier pattern is formed.

20. The manufacturing method of the semiconductor device according to claim 11, wherein an upper surface of the barrier pattern and an upper surface of the gate structure are coplanar or the upper surface of the barrier pattern is higher than the upper surface of the gate structure in the vertical direction.
